(19) United States
(12) Patent Application Publication
(10) Pub. No.: US 2025/0318171 A1
(43) Pub. Date: Oct. 9, 2025

(54) SOURCE/DRAIN STRUCTURES WITH IMPROVED EPITAXIAL FORMATION

(71) Applicant: INTERNATIONAL BUSINESS MACHINES CORPORATION, Armonk, NY (US)

(72) Inventors: Jianwei Peng, Clifton Park, NY (US); Ruilong Xie, Niskayuna, NY (US); Nicolas Jean Loubet, Guilderland, NY (US); Julien Frougier, Albany, NY (US)

(21) Appl. No.: 18/625,920

(22) Filed: Apr. 3, 2024

(51) Int. Cl. H01L 29/66; H01L 29/08; H01L 29/423; H01L 29/775; H01L 29/786

(52) U.S. Cl. CPC H10D 30/031; H10D 30/014; H10D 30/43; H10D 30/6757; H10D 62/151; H10D 30/6735

(57) ABSTRACT

Semiconductor devices and methods of forming the same include a substrate having a platform that is raised relative to a remainder of the substrate's surface. The platform includes a stepped profile with a top portion having a smaller width than a width of a base portion. A channel layer is over the platform. A gate stack is on and around the channel layer. First sidewall spacers are on the gate stack, above the channel layer. Source/drain structures are over the platform.

### BACKGROUND

The present invention generally relates to semiconductor device fabrication and, more particularly, to formation of source/drain structures with improved consistency.

Fabrication of nanosheet field effect transistors (FETs) can be performed with a process that selectively etches a stack of different semiconductor materials. In some cases, removal of a particular sacrificial layer can cause uneven etching of the other semiconductor layers. This results in remnants of certain semiconductor materials remaining in the source/drain region, which can interfere with epitaxial deposition of the source/drain structures.

### SUMMARY

A semiconductor device includes a substrate having a platform that is raised relative to a remainder of the substrate's surface. The platform includes a stepped profile with a top portion having a smaller width than a width of a base portion. A channel layer is over the platform. A gate stack is on and around the channel layer. First sidewall spacers are on the gate stack, above the channel layer. Source/drain structures are over the platform.

A semiconductor device includes a substrate having a platform that is raised relative to a remainder of the substrate's surface. The platform includes a stepped profile with a top portion having a smaller width than a width of a base portion. A channel layer is over the platform. A gate stack is on and around the channel layer. First sidewall spacers are on the gate stack, above the channel layer, that have an L-shaped cross-section, with a lower portion extending laterally into the gate stack. Source/drain structures are over the platform. A self-aligned substrate isolation layer, between the gate stack and the platform, includes a portion that extends vertically along sidewalls of the top portion of the platform.

A method of forming a semiconductor device includes forming a stack of alternating channel layers and second sacrificial layers over a first sacrificial layer. The channel layers are recessed relative to the second sacrificial layers using a selective isotropic etch. The first sacrificial layer is etched away in a source/drain region with an etch that selectively etches the second sacrificial layers back to be even with recessed sidewalls of the channel layers. A dielectric layer is formed around the channel layers and the second sacrificial layers in the source/drain region to form sidewall spacers and to fill a space between the stack and an underlying substrate. The stack is etched away in a source/drain region. Source/drain structures are grown between the sidewall spacers from side surfaces of the channel layers in a channel region.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device with improved epitaxial formation of source/drain structures, showing a set of cross-sectional planes, in accordance with an embodiment of the present invention;

FIG. 2 is a set of cross-sectional views of a step in the formation of a semiconductor device with improved epitaxial formation of source/drain structures, showing a set of alternating channel layers and sacrificial layers, in accordance with an embodiment of the present invention;

FIG. 3 is a set of cross-sectional views of a step in the formation of a semiconductor device with improved epitaxial formation of source/drain structures, showing the formation of stacks from the alternating channel layers and sacrificial layers, in accordance with an embodiment of the present invention;

FIG. 4 is a set of cross-sectional views of a step in the formation of a semiconductor device with improved epitaxial formation of source/drain structures, showing an isotropic etch that recesses the channel layers relative to the sacrificial layers, in accordance with an embodiment of the present invention;

FIG. 5 is a set of cross-sectional views of a step in the formation of a semiconductor device with improved epitaxial formation of source/drain structures, showing the deposition of dummy gate material over the stacks, in accordance with an embodiment of the present invention;

FIG. 6 is a set of cross-sectional views of a step in the formation of a semiconductor device with improved epitaxial formation of source/drain structures, showing the formation of dummy gates over the stacks, in accordance with an embodiment of the present invention;

FIG. 7 is a set of cross-sectional views of a step in the formation of a semiconductor device with improved epitaxial formation of source/drain structures, showing an isotropic etch of a protective dielectric layer, in accordance with an embodiment of the present invention;

FIG. 8 is a set of cross-sectional views of a step in the formation of a semiconductor device with improved epitaxial formation of source/drain structures, showing the removal of a first sacrificial layer that also partially etches back the alternating sacrificial layers, in accordance with an embodiment of the present invention;

FIG. 9 is a set of cross-sectional views of a step in the formation of a semiconductor device with improved epitaxial formation of source/drain structures, showing the formation of sidewall spacers and a self-aligned substrate isolation layer, in accordance with an embodiment of the present invention;

FIG. 10 is a set of cross-sectional views of a step in the formation of a semiconductor device with improved epitaxial formation of source/drain structures, showing the removal of the stack of alternating layers from a source/drain region, in accordance with an embodiment of the present invention;

FIG. 11 is a set of cross-sectional views of a step in the formation of a semiconductor device with improved epitaxial formation of source/drain structures, showing the formation of source/drain structures in the source/drain region, in accordance with an embodiment of the present invention;

FIG. 12 is a set of cross-sectional views of a step in the formation of a semiconductor device with improved epitaxial formation of source/drain structures, showing the removal of the dummy gates to expose the stack of alternating layers in a channel region, in accordance with an embodiment of the present invention;

FIG. 13 is a set of cross-sectional views of a step in the formation of a semiconductor device with improved epitaxial formation of source/drain structures, showing the removal of the sacrificial layers from the stack in the channel region, in accordance with an embodiment of the present invention;

FIG. 14 is a set of cross-sectional views of a step in the formation of a semiconductor device with improved epitaxial formation of source/drain structures, showing the formation of a gate stack around the channel layers, in accordance with an embodiment of the present invention;

FIG. 15 is a block/flow diagram of a method for forming a semiconductor device with improved epitaxial formation of source/drain structures.

### DETAILED DESCRIPTION

To improve the formation of source/drain structures in a nanosheet field effect transistor (FET), a stack of nanosheets may be formed with channel layers that are wider than are called for in the final device. The channel layers may be selectively etched back, so that when a first sacrificial layer is later etched away, a partial etch of a set of second sacrificial layers occurs to put them back in line with the sidewalls of the channel layers.

Referring now to FIG. 1, a top-down view of a semiconductor device is shown, illustrating a set of different cross-sectional planes. This view shows a channel structure 102, with gate structures 104 running perpendicularly across the channel structure 102. The relative dimensions of the channel structure 102 and the gate structures 104 are not drawn to scale and are shown solely to identify qualitative features of the following cross-sectional views.

The cross-sectional views include XX, which is a view that cut parallel to the channel structure 102, Y₁Y₁, which is a view that cuts parallel to and through a gate structure 104, and Y₂Y₂, which is a view that cuts parallel to the gate structures 104 but through a source/drain region. The following figures will show each of these cross-sectional views in tandem to illustrate steps in the fabrication of a semiconductor device, but it should be understood that some steps and some structures of the device may not be shown.

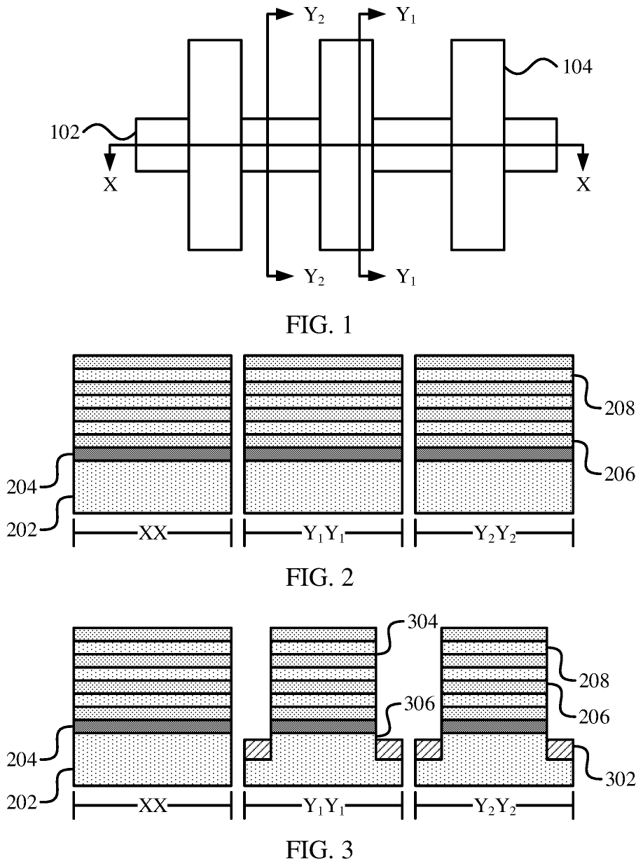

Referring now to FIG. 2, a set of cross-sectional views are shown of a step in the fabrication of a semiconductor device. A semiconductor substrate 202 is shown, with a stack of semiconductor layers formed on top of it. The stack includes a first sacrificial semiconductor layer 204. Above the first sacrificial semiconductor layer 204 are a set of alternating semiconductor layers, including channel layers 208 and second sacrificial semiconductor layers 206.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate.

The first sacrificial semiconductor layer 204, the second sacrificial semiconductor layers 206, and the channel layers 208 may be formed by successive epitaxial growth processes. These layers may be formed by crystallographically compatible materials, where the crystal structure of each material is similar to the crystal structure of the others. The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

In embodiments where the semiconductor substrate 202 is formed from silicon, the channel layers 208 may similarly be formed from silicon while the first sacrificial semiconductor layer 204 and the second sacrificial semiconductor layers 206 may be formed from silicon germanium with differing germanium concentrations. For example, the silicon germanium of the first sacrificial semiconductor layer 204 may have a germanium concentration of about 25%, while the silicon germanium of the second sacrificial semiconductor layers 206 may have a germanium concentration of about 55%. It should be understood that any appropriate concentrations may be used instead, and that these concentrations are selected to be compatible with an etch process that will selectively remove the first sacrificial semiconductor layer 204 before the second sacrificial semiconductor layers 206 and the channel layers 208.

Referring now to FIG. 3, a set of cross-sectional views are shown of a step in the fabrication of a semiconductor device. Trenches are formed with a photolithographic mask and a subsequent anisotropic etch that penetrates through the stack of layers and into the semiconductor substrate 202. The etch forms semiconductor stack 304 and substrate platform 306. Shallow trench isolation (STI) structures 302 are formed in the trenches.

The photolithographic process uses radiation to create a pattern mask on top of the layers. Specifically, a pattern is produced by applying a photoresist to the surface to be etched. The photoresist is exposed to a pattern of radiation, in this instance corresponding to the shape of the semiconductor stack 304 (or its negative). The pattern is developed into the photoresist utilizing a resist developer. Once the patterning of the photoresist is completed, the sections covered by the photoresist are protected while the exposed regions are removed using a selective etching process that removes the unprotected regions.

An anisotropic etch such as reactive ion etching (RIE) may be used to selectively remove material and form the semiconductor stack 304. RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation. As used herein, the term “selective” in reference to a material removal process denotes that the rate of material removal for a first material is greater than the rate of removal for at least another material of the structure to which the material removal process is being applied.

The STI structures 302 may be formed by deposition of a dielectric material by any appropriate deposition process. For example, silicon dioxide may be deposited in the trenches using a flowable chemical vapor deposition (CVD) process. It is specifically contemplated that the STI structures 302 may be formed to a height that is slightly below the top surface of the substrate platform 306, thereby leaving a portion of the substrate platform 306 that is exposed near the top surface thereof.

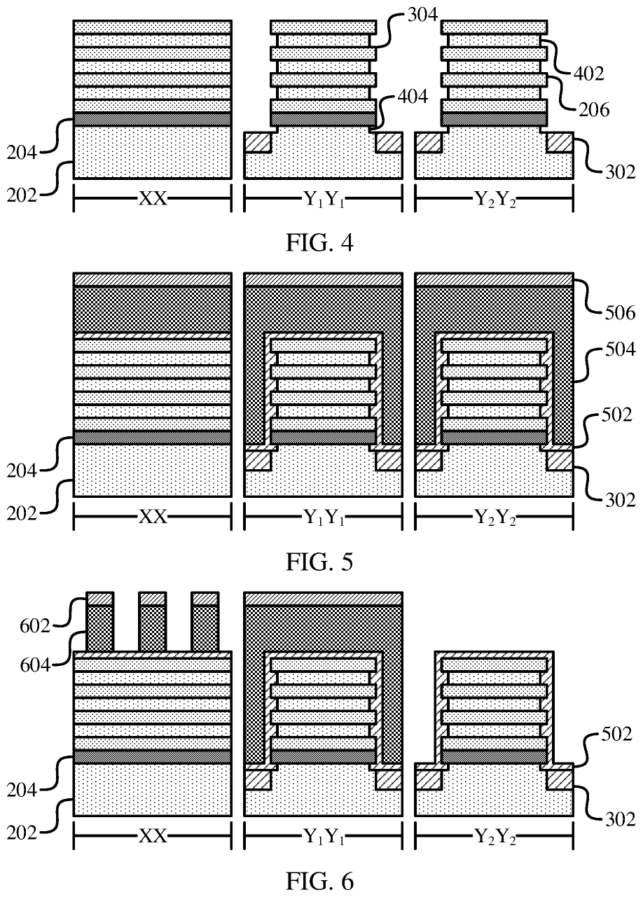

Referring now to FIG. 4, a set of cross-sectional views are shown of a step in the fabrication of a semiconductor device. A selective isotropic etch is performed that preferentially removes material from the channel layers 208, forming recessed channel layers 402. This etch also removes material from the substrate platform 306, creating stepped platform 404, having a stepped profile when viewed in cross-section. In some embodiments, this etch may remove about 2 nm of channel material (e.g., silicon) from exposed surfaces thereof. For example, the selective etch may include a tetramethylammonium hydroxide (TMAH) or ammonium hydroxide (NH₄OH) etch chemistry to preferentially remove silicon material preferentially to silicon germanium. As shown in cross-section Y₁Y₁, the recessed channel layers 402 have a width that is approximately the same as a smaller width of the stepped platform 404, but that is less than the width of the base of the stepped platform 404.

Referring now to FIG. 5, a set of cross-sectional views are shown of a step in the fabrication of a semiconductor device. A thin dielectric layer 502 is conformally deposited over the semiconductor stack 304. The thin dielectric layer 502 may be deposited by any appropriate conformal process, such as CVD or atomic layer deposition (ALD), and fills the recesses left by forming recessed channel layers 402. A dummy gate layer 504, formed from amorphous silicon for example, may be deposited over the semiconductor stack 304, and a hardmask layer 506, formed from silicon nitride for example, may be deposited over the dummy gate layer 504.

These layers may be formed by any appropriate process including, e.g., CVD, physical vapor deposition (PVD), ALD, or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 6, a set of cross-sectional views are shown of a step in the fabrication of a semiconductor device. Dummy gates 604 are formed from the dummy gate layer 504, for example by forming a pattern 602 in the hardmask layer 506 using a photolithographic process and anisotropic etch, followed by a selective anisotropic etch that removes the exposed amorphous silicon of the dummy gate layer 504 without harming the protective dielectric layer 502.

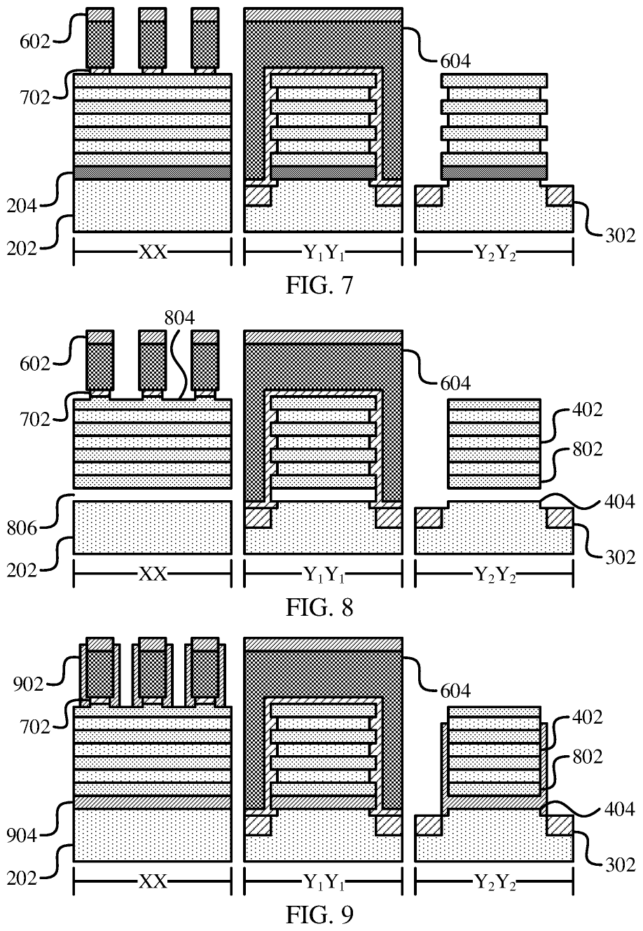

Referring now to FIG. 7, a set of cross-sectional views are shown of a step in the fabrication of a semiconductor device. The dielectric layer 502 is isotropically etched away. This removes the dielectric layer 502 entirely from the source/drain regions, as shown in cross-section Y₂Y₂, but only recesses the dielectric material in areas where it is protected by the dummy gates 604, as shown in cross-section XX. The recessed dielectric layer 702 is etched back.

Referring now to FIG. 8, a set of cross-sectional views are shown of a step in the fabrication of a semiconductor device. A selective etch is performed that targets the first sacrificial semiconductor layer 204, etching it away completely. During this etch, some material will also be removed from exposed surfaces of the second sacrificial semiconductor layers 206, producing recessed sacrificial layers 802. The etch is timed such that the amount of material removed from the second sacrificial semiconductor layers 206 corresponds to the amount of material removed during the formation of recessed channel layers 402, so that side surfaces of the recessed sacrificial layers 802 align with side surfaces of the recessed channel layers 402. A small amount of channel material may also be removed during this stage, which may further be accounted for in the timing of the selective etches.

A top sacrificial layer 804 is furthermore exposed on its top surface, and so will be partially etched on that surface. This creates a top surface of the top sacrificial layer 804 that matches the recessed dielectric layer 702 under the dummy gates 604. The removal of the first sacrificial semiconductor layer 204 leaves a gap 806 between the lowermost recessed sacrificial layer 802 and the stepped platform 404.

Referring now to FIG. 9, a set of cross-sectional views are shown of a step in the fabrication of a semiconductor device. A spacer layer 902 is conformally deposited using any appropriate process, such as CVD or ALD. Due to the recess of the recessed dielectric layer 702 and the top sacrificial layer 804, the spacer layer 902 extends laterally underneath the edges of the dummy gates 604, producing an L-shaped cross-section. The deposition may include silicon nitride and further fills the gap 806 to form self-aligned substrate isolation layer 904 between the recessed sacrificial layers and the stepped platform 404.

The self-aligned substrate isolation layer 904 includes portions that extend vertically along sidewalls of the stepped platform 404, in particular filling a lateral space between sidewalls of the top portion of the stepped platform 404 and the sidewalls of the bottom portion of the stepped platform 404.

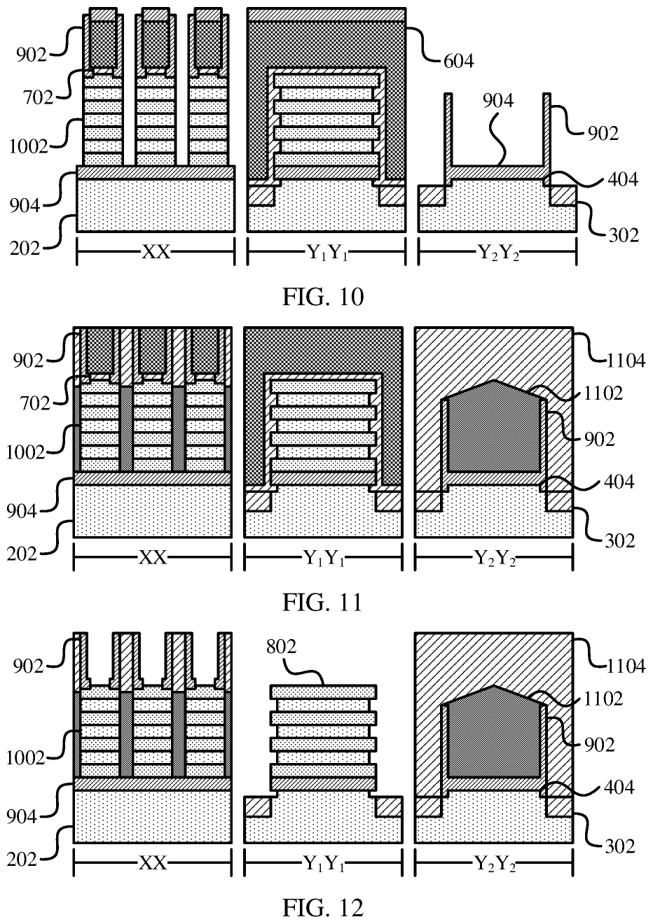

Referring now to FIG. 10, a set of cross-sectional views are shown of a step in the fabrication of a semiconductor device. Exposed portions of the semiconductor stack 304 are etched away, including any portions of the recessed channel layers 402 and the recessed sacrificial layers 802 that are not covered by the dummy gates 604 and the spacer layer 902. Any appropriately anisotropic etch may be used. This etch leaves behind channels 1002 under the dummy gates 604.

In particular, the recessed channel layers 402 and recessed sacrificial layers 802 may be completely removed from the source/drain regions, as shown in cross-section Y₂Y₂. Because the layers were recessed to the same width, the formation of the spacer layer 902 does not create any shadows or protected regions, which might otherwise occur if the layers had different widths.

Referring now to FIG. 11, a set of cross-sectional views are shown of a step in the fabrication of a semiconductor device. Source/drain structures 1102 are epitaxially grown from exposed surfaces of the channels 1002. The source/drain structures 1102 may include a dopant that is appropriate to a device polarity of the FET being formed. For example, the source/drain structures 1102 may include an n-type or p-type dopant that is added in situ during the epitaxial deposition of these structures. After formation of the source/drain structures 1102, an interlayer dielectric 1104 may be formed by the deposition of, e.g., silicon dioxide.

The epitaxial growth of the source/drain structures causes semiconductor material to be deposited between the spacer layers 902 and on the self-aligned substrate isolation layer 904, filling the space defined by these structures. An interface between the spacer layers 902 and the source/drain structures 1102 will be flat as a result of pre-etching the channel layers 208 to keep the ends of the second sacrificial semiconductor layers 206 even with them after the etch of the latter. Additionally, there will be no remnants of the channel layers on the spacer layers 902, which could otherwise interfere with the epitaxial growth of the source/drain structures 1102.

A chemical mechanical planarization (CMP) process may be performed after deposition of the dielectric material to expose the dummy gates 604. CMP is performed using, e.g., a chemical or granular slurry and mechanical force to gradually remove upper layers of the device. The slurry may be formulated to be unable to dissolve, for example, the work function metal layer material, resulting in the CMP process's inability to proceed any farther than that layer.

Referring now to FIG. 12, a set of cross-sectional views are shown of a step in the fabrication of a semiconductor device. The dummy gates 604 are etched away using any appropriately selective etch, exposing the recessed dielectric layer 702. The recessed dielectric layer 702 is also etched away with a selective isotropic etch, such as a wet or dry chemical etch. This exposes the channels 1002 and the remainder of the recessed sacrificial layers 802.

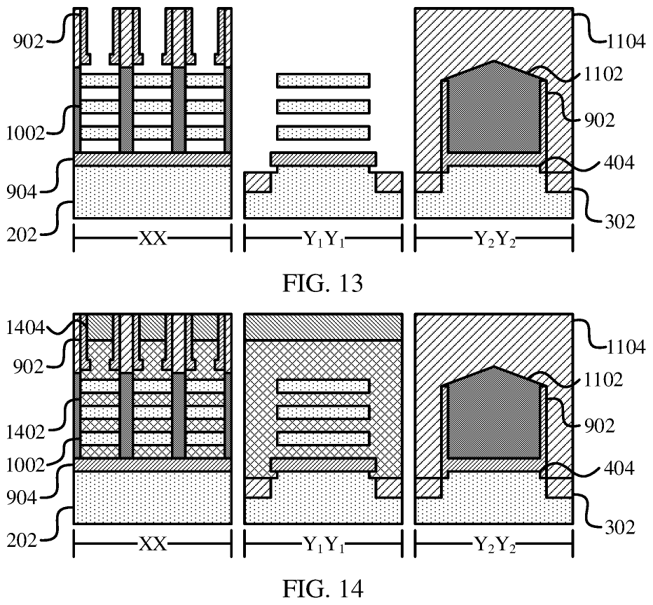

Referring now to FIG. 13, a set of cross-sectional views are shown of a step in the fabrication of a semiconductor device. The remainder of the recessed sacrificial layers 802 is selectively etched away, leaving channels 1002 suspended by the source/drain structures 1102.

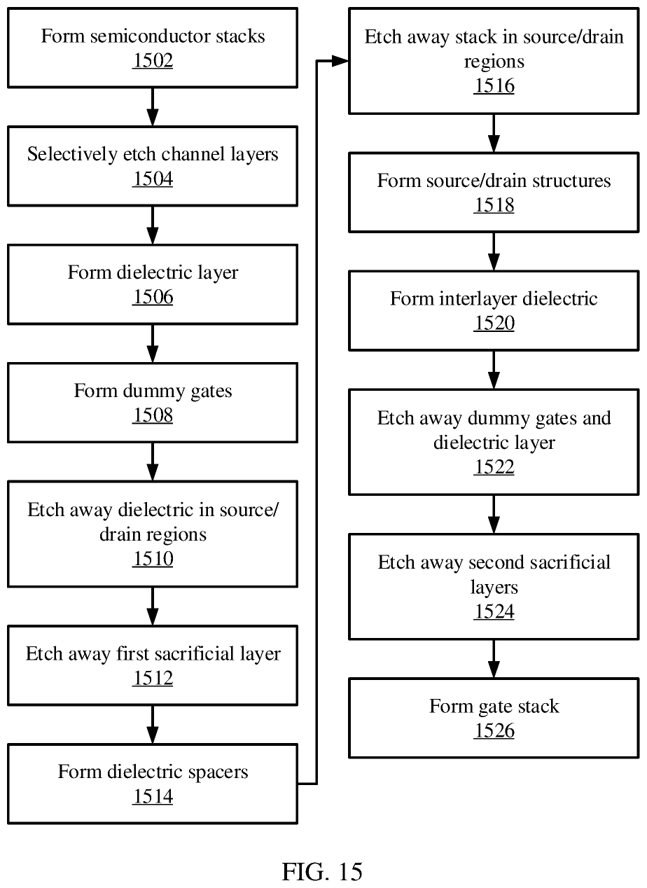

Referring now to FIG. 14, a set of cross-sectional views are shown of a step in the fabrication of a semiconductor device. A gate stack 1402 is formed on and around the channels 1002. The gate stack 1402 may include, for example, a gate dielectric layer, an optional work function metal layer, and a gate conductor. The spacers 902 have a lower portion that extends laterally into the body of the gate stack. A self-aligned contact cap 1404 may then be deposited over the gate stack 1402. Conductive contacts may be formed to the gate stack 1402 and to the source/drain structures 1102 as needed.

The gate dielectric of the gate stack 1402 may include a high-k dielectric. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The gate conductor of the gate stack 1402 may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon.

If one is used, a work function metal layer may include a p-type work function metal layer or an n-type work function metal layer, in accordance with whether the FET is a p-type or n-type transistor. As used herein, a “p-type work function metal layer” is a metal layer that effectuates a p-type threshold voltage shift. In one embodiment, the work function of the p-type work function metal layer ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, a p-type work function metal layer may be formed from titanium nitride, titanium aluminum nitride, ruthenium, platinum, molybdenum, cobalt, and alloys and combinations thereof.

As used herein, an “n-type work function metal layer” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is formed from at least one of titanium aluminum, tantalum nitride, titanium nitride, hafnium nitride, hafnium silicon, or combinations thereof. It should be understood that titanium nitride may play the role of an n-type work function metal or a p-type work function metal, depending on the conditions of its deposition.

Referring now to FIG. 15, a method for forming a semiconductor device is shown. Block 1502 forms the semiconductor stacks 304, for example including a series of epitaxial depositions to form the first sacrificial semiconductor layer 204, the second sacrificial semiconductor layers 206, and the channel layers 208, followed by patterning and etching. Block 1504 then recesses the channel layers 208 using a selective etch to form recessed channel layers 402.

Block 1506 forms a dielectric layer 502 over the stacks 304, for example by conformal deposition of silicon dioxide. Block 1508 then forms the dummy gates 604, for example by depositing amorphous silicon, patterning it, and etching it. The formation of the dummy gates 604 leaves source/drain regions exposed, and block 1510 etches away the dielectric layer in the source/drain regions.

Block 1512 etches away the first sacrificial semiconductor layer 204, which also partially etches the second sacrificial semiconductor layers 206, leaving recessed sacrificial layers 802 that line up with the recessed channel layers 402. Block 1514 then conformally deposits a dielectric, such as silicon nitride, to cover sidewalls of the exposed surfaces and to fill the gap 806 left by removal of the first sacrificial semiconductor layer 204. The dielectric material may be selectively etched away from exposed horizontal surfaces using an anisotropic etch, leaving spacers 902 and self-aligned substrate isolation layer 904. Block 1516 then etches away portions of the stack 304 in the source/drain regions, with portions in gate regions being protected by the dummy gates 604 and the spacers 902.

Block 1518 forms source/drain structures 1102 from exposed portions of the channels 1002, for example including in situ doping. Block 1520 then deposits an interlayer dielectric 1104 to cover the source/drain structures 1102. Block 1522 etches away the dummy gates 604 and remaining portions of the recessed dielectric layer 702. Block 1524 etches away the remaining portions of the recessed sacrificial layers 802. Block 1526 forms a gate stack on and around the suspended channels 1002.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of source/drain structures with improved epitaxial formation (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

The invention claimed is:

1. A semiconductor device, comprising:
a substrate having a platform that is raised relative to a remainder of a top surface of the substrate, wherein the platform includes a stepped profile with a top portion having a smaller width than a width of a base portion;
a channel layer over the platform;
a gate stack on and around the channel layer;
first sidewall spacers on the gate stack, above the channel layer; and
source/drain structures over the platform.

2. The semiconductor device of claim 1, wherein the first sidewall spacers have an L-shaped cross-section, with a lower portion extending laterally into the gate stack.

3. The semiconductor device of claim 1, wherein the channel layer and the source/drain structures have approximately a same width as the width of the top portion of the platform.

4. The semiconductor device of claim 1, further comprising a self-aligned substrate isolation layer between the gate stack and the platform.

5. The semiconductor device of claim 4, wherein the self-aligned substrate isolation layer has a width that is approximately the same as the width of the base portion of the platform.

6. The semiconductor device of claim 4, wherein the self-aligned substrate isolation layer includes a portion that extends vertically along sidewalls of the top portion of the platform.

7. The semiconductor device of claim 1, wherein the source/drain structures include a dielectric spacer on sidewalls of an epitaxially grown, doped semiconductor between the epitaxially grown, doped semiconductor and the platform.

8. The semiconductor device of claim 7, wherein the dielectric spacer has a flat interface with the sidewalls of the epitaxially grown, doped semiconductor.

9. The semiconductor device of claim 7, wherein the source/drain structures lack channel remnants in the dielectric spacer.

10. The semiconductor device of claim 1, further comprising shallow trench isolation (STI) structures on respective sides of the platform, wherein top surfaces of the STI structures have a same height as a top surface of the base portion of the platform.

11. A semiconductor device, comprising:
a substrate having a platform that is raised relative to a remainder of a top surface of the substrate, wherein the platform includes a stepped profile with a top portion having a smaller width than a width of a base portion;
a channel layer over the platform;
a gate stack on and around the channel layer;
first sidewall spacers on the gate stack, above the channel layer, that have an L-shaped cross-section, with a lower portion extending laterally into the gate stack;
source/drain structures over the platform; and
a self-aligned substrate isolation layer, between the gate stack and the platform, that includes a portion that extends vertically along sidewalls of the top portion of the platform.

12. The semiconductor device of claim 11, wherein the channel layer and the source/drain structures have approximately a same width as the width of the top portion of the platform.

13. The semiconductor device of claim 11, wherein the self-aligned substrate isolation layer has a width that is approximately the same as the width of the base portion of the platform.

14. The semiconductor device of claim 11, wherein the source/drain structures include a dielectric spacer on sidewalls of an epitaxially grown, doped semiconductor between the epitaxially grown, doped semiconductor and the platform, wherein the dielectric spacer have a flat interface with the sidewalls of the epitaxially grown, doped semiconductor.

15. The semiconductor device of claim 11, further comprising shallow trench isolation (STI) structures on respective sides of the platform, wherein top surfaces of the STI structures have a same height as a top surface of the base portion of the platform.

16. A method of forming a semiconductor device, comprising:
forming a stack of alternating channel layers and second sacrificial layers over a first sacrificial layer;
recessing the channel layers relative to the second sacrificial layers using a selective isotropic etch;
etching away the first sacrificial layer in a source/drain region with an etch that selectively etches the second sacrificial layers back to be even with recessed sidewalls of the channel layers;
forming a dielectric layer around the channel layers and the second sacrificial layers in the source/drain region to form sidewall spacers and to fill a space between the stack and an underlying substrate;
etching away the stack in a source/drain region; and
growing source/drain structures between the sidewall spacers from side surfaces of the channel layers in a channel region.

17. The method of claim 16, further comprising:
depositing a protective dielectric layer over the stack before etching away the first sacrificial layer in the source/drain region; and
etching away the protective dielectric layer in the source/drain region with an isotropic etch that partially recesses the protective dielectric layer in the channel region.

18. The method of claim 17, wherein forming the dielectric layer around the channel layers and the second sacrificial layer is performed with a conformal deposition that further deposits sidewall spacers on a dummy gate and fills a recess left by the partial recess of the protective dielectric layer.

19. The method of claim 16, wherein the recessing the channel layers further laterally recesses an exposed top portion of the underlying substrate.

20. The method of claim 16, wherein recessing the channel layers is performed using a tetramethylammonium hydroxide (TMAH) or ammonium hydroxide (NH₄OH) etch chemistry that selectively removes silicon over silicon germanium.
